(19) United States
(12) Patent Application Publication
(10) Pub. No.: US 2013/0050945 A1
(43) Pub. Date: Feb. 28, 2013

(54) Electronic Device Enclosures with Engagement Features

(71) Applicants: Vinh Diep, Palo Alto, CA (US); Dominic Dolci, Berkeley, CA (US); Chiew-Siang Goh, San Jose, CA (US); Alexander Michael Kwan, Los Altos Hills, CA (US); Cesar Lozano Villarreal, Sunnyvale, CA (US)

(72) Inventors: Vinh Diep, Palo Alto, CA (US); Dominic Dolci, Berkeley, CA (US); Chiew-Siang Goh, San Jose, CA (US); Alexander Michael Kwan, Los Altos Hills, CA (US); Cesar Lozano Villarreal, Sunnyvale, CA (US)

(21) Appl. No.: 13/223,030

(22) Filed: Aug. 31, 2011

(51) Int. Cl. H05K 5/00; H05K 5/02; A47B 87/00; H05K 7/20

(52) U.S. Cl. 361/704; 361/807; 361/752; 312/111

(57) ABSTRACT

An electronic device may have electronic device housing structures in which electronic components such as integrated circuits and connectors may be mounted. The electronic device housing structures may include an upper housing having a planar upper surface member and four perpendicular housing sidewall structures. The housing sidewall structures of the upper housing may have edges that form a rectangular opening with curved corners. A lower housing may have structures forming a rectangular lip that is configured to be received within the rectangular opening in the upper housing. Engagement structures such as inwardly protruding hook structures on the upper housing and snap structures on the rectangular lip may be used in attaching the upper and lower housings. The snap structures may each have a rectangular main opening and lateral extension portions that extend the width of the main opening along the edge of the lip.

### BACKGROUND

This relates generally to electronic devices, and more particularly, to electronic device housings.

Electronic devices contain electronic components that are mounted within housings. In some devices, housings are formed from mating housing structures. Features such as interlocking tabs and hooks may be used in attaching housing structures together during assembly. If care is not taken, however, the features that are used in interconnecting housing structures may consume undesired amounts of volume within a device housing. This may result in a bulky housing design or reduced interior volume for mounting device components.

It would therefore be desirable to be able to provide improved housing configurations for electronic devices.

### SUMMARY

An electronic device may include electronic components such as integrated circuits and connectors. The electronic components may be mounted within housing structures.

The housing structures may include an upper housing having a planar upper surface member and four perpendicular housing sidewall structures. The housing sidewall structures of the upper housing may have edges that form a rectangular opening with curved corners. A lower housing may have structures forming a rectangular lip. The lip may be formed from a wall structure with a rectangular outline that is configured to be received within the rectangular opening in the upper housing.

Engagement structures such as inwardly protruding hook structures on the upper housing and corresponding snap structures on the rectangular lip may be used in attaching the upper and lower housings. The hook structures may have angled leading edges to form a ramp that facilitates assembly of the upper and lower housings and may have trailing edges with an angle that helps bias the hook structures away from the snap structures to reduce rattling following assembly.

The snap structures may each have a rectangular main opening and lateral extension portions that extend the width of the main opening along the edge of the lip so that the snap structure opening forms a T shape. A heat sink within the electronic device may be used to dissipate heat from the internal components. The heat sink may have a vertical wall portion adjacent to at least one of the hooks and snaps to help prevent the hooks and snaps from becoming disengaged when electronic device is subjected to a drop event.

Further features of the invention, its nature and various advantages will be more apparent from the accompanying drawings and the following detailed description of the preferred embodiments.

### BRIEF DESCRIPTION OF THE DRAWINGS

FIG. 1 is an exploded perspective view of an illustrative electronic device with a housing in accordance with an embodiment of the present invention.

FIG. 2 is a perspective view of an underside portion of an upper housing structure in accordance with an embodiment of the present invention.

FIG. 3 is a side view of an illustrative electronic device housing showing how a lower housing portion may have protruding features that engage with corresponding recessed features in an upper housing in accordance with an embodiment of the present invention.

FIG. 4 is a cross-sectional side view of an illustrative electronic device housing in which components have been mounted in accordance with an embodiment of the present invention.

FIG. 5 is a perspective view of a portion of a sidewall structure on a lower housing that forms a lip having a flexing snap structure of the type that may be used as a housing engagement feature for coupling housing structures together in accordance with an embodiment of the present invention.

FIG. 6 is a diagram of a housing structure with a hook structure and a housing structure with a mating snap structure that may be used to connect the housing structures together in accordance with an embodiment of the present invention.

FIG. 7 is a cross-sectional side view of an illustrative housing structure with a hook and a housing structure with a mating snap in a configuration in which the housing structures are being moved towards each other to engage the hook and snap in accordance with an embodiment of the present invention.

FIG. 8 is a cross-sectional side view of the illustrative housing structures of FIG. 7 in a configuration following insertion of the hook into the snap in accordance with an embodiment of the present invention.

FIG. 9 is a cross-sectional side view of an illustrative hook on an electronic device housing sidewall showing how the hook may have upper and lower surfaces that are angled to form a leading edge ramp to facilitate assembly with snap features while providing a trailing edge ramp that helps form an anti-rattle bias following assembly in accordance with an embodiment of the present invention.

### DETAILED DESCRIPTION

Electronic devices may be provided with housing structures. The housing structures may have engagement features such as features with protrusions (sometimes referred to as hooks) and features with mating openings (sometimes referred to as snaps).

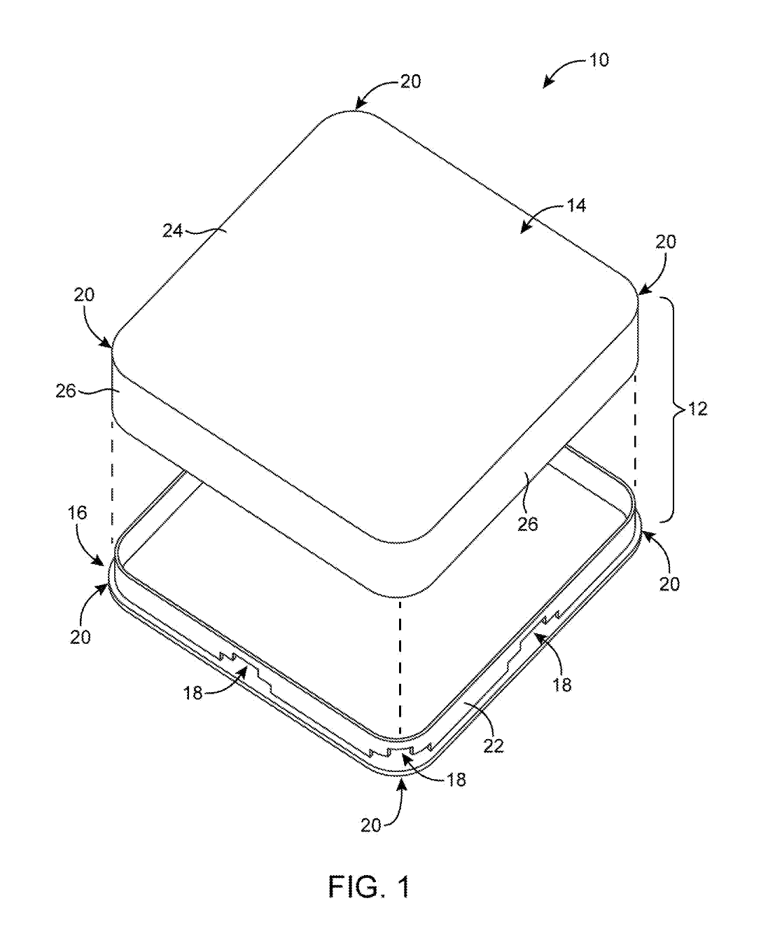

An illustrative electronic device of the type that may be provided with housing structures having engagement features is shown in FIG. 1. Electronic device 10 of FIG. 1 may be a computer, a set-top box, a wireless access point, a portable electronic device, or any other suitable electronic equipment. Configurations for electronic device 10 in which device 10 is implemented as a wireless access point are sometimes described herein as an example. This is, however, merely illustrative. Electronic device 10 may include any suitable type of electronic equipment if desired.

As shown in the exploded perspective view of FIG. 1, electronic device 10 may have a housing such as housing 12. Housing 12 may be formed from materials such as plastic, glass, ceramic, metal, carbon fiber, fiberglass, and other fiber composites, other materials, or combinations of these materials. Housing 12 may have one or more parts. In the illustrative configuration of FIG. 1, housing 12 has two parts: upper housing portion 14 and lower housing portion 16. If desired, housing 12 may have more than two parts. Upper housing 14 may have a planar upper surface such as upper housing wall 24 or other planar housing member and may have sidewalls such as planar vertical sidewalls 26 that extend perpendicularly from the planar upper housing member (as an example). Lower housing 16 may be formed from a housing member with a substantially planar shape and a peripheral outline that matches the peripheral outline of upper housing 14.

As shown in FIG. 1, upper housing 14 and lower housing 16 may have corners 20. Corners 20 may be rounded (as shown in FIG. 1), may be square, or may have other suitable shapes.

When assembled together to enclose internal device components, wall (lip) 22 of lower housing 16 may nest within the inner periphery of wall 26 of upper housing 14. Engagement features on upper and lower housings 14 and 16 may be used to hold upper and lower housings 14 and 16 together following assembly. With one suitable arrangement, housings 14 and 16 may have engagement structures such as hooks (protrusions) and snaps (housing structures with openings that receive the protrusions). The hooks may be formed on upper housing 14 and the snaps may be formed on lower housing 16 (e.g., in lip 22), the hooks may be formed on lower housing 16 and the snaps may be formed on upper housing 14 (e.g., in wall 26), or combinations of upper and lower housing mounting arrangements may be used for the hooks and the snaps. Snap structures 18 may, if desired, be formed on at least some of the edges of lip 22 and each of the four corners of lip 22.

In the illustrative arrangement of FIG. 1, lower housing 16 has been provided with snaps 18 that mate with corresponding hooks on the interior of upper housing 14. Snaps 18 and the corresponding hooks in upper housing 14 may be formed along the straight sides of housing 16 and housing 14 and may, if desired, be formed at corners 20. For example, each of the four corners 20 of lower housing 16 may be provided with a corresponding one of snaps 18 (as an example). This helps hold housings 14 and 16 together at their corners.

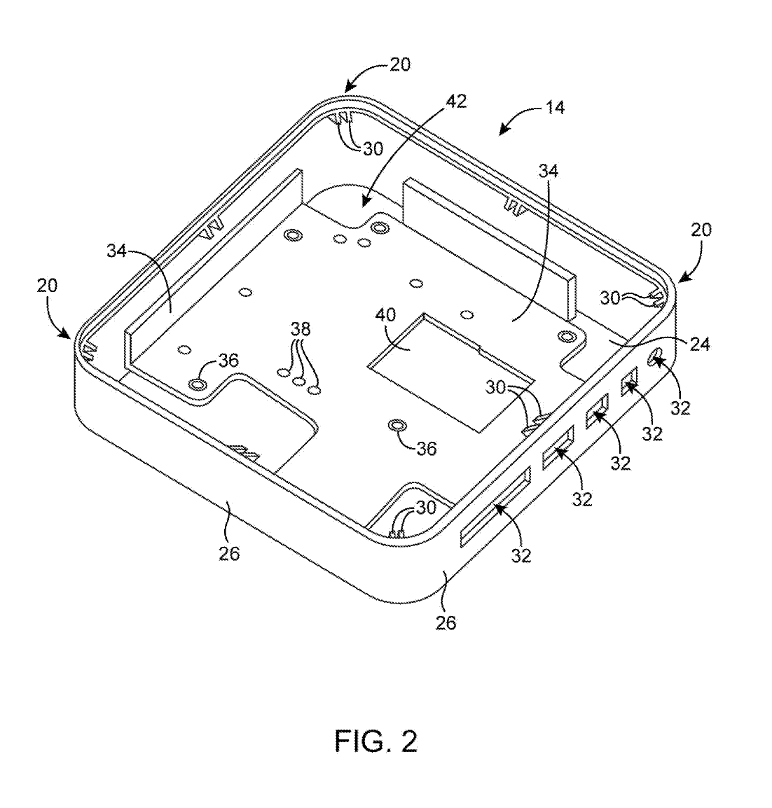

FIG. 2 is an interior perspective view of an illustrative configuration that may be used for upper housing 12. Vertical sidewalls 26 may extend so that they run perpendicular to planar member 24. The exposed edges of sidewalls 26 may form an opening with a rectangular periphery. The opening may have a shape that is slightly larger than lip 22 of housing 16 (FIG. 1), so that lip 22 may be received within the opening defined by housing sidewalls 26 during assembly.

As shown in FIG. 2, openings such as openings 32 may be formed in housing sidewalls 26. Openings 32 may have any suitable shapes (e.g., rectangular, round, etc.). Openings 32 may be used to accommodate connectors (e.g., Ethernet connectors, HDMI connectors, power adapter connectors, Universal Serial Bus connectors, etc.).

Protrusions such as hooks 30 may be provided around the inner periphery of sidewalls 26. A shown in FIG. 2, hooks 30 may be formed at midpoints along the straight sidewall segments of housing 14 and at each of the four corners 20 of housing 14. Internal device components may be mounted within housing 14. The internal device components may include wireless integrated circuits such as integrated circuits for forming wireless access point communications circuitry, etc.

To help dissipate heat that is generated by internal components, heat sink structures such as heat sink 34 may be mounted to the interior of housing 14. Heat sink 34 may be formed from one or more metal structures (e.g., structures formed from copper, aluminum, or other metals) or other structures with a relatively high thermal conductivity. Portions of heat sink 34 may extend vertically (e.g., parallel to vertical sidewalls 26) and portions of heat sink 34 may extend laterally (e.g., parallel to the planar housing structure that forms top surface 24 of housing 14 (FIG. 1). Heat sink 34 may be mounted within housing 12 using adhesive, heat stake structures (see, e.g., heat stakes 38), metal support members (e.g., threaded metal structures 36 for receiving threaded fasteners such as screws that screw printed circuit boards and other structures to heat sink 34), and/or other suitable fastening mechanisms. Openings such as corner opening 42 and recesses such as shallow rectangular recess 40 or recesses of other shapes may be formed in heat sink 34 (e.g., to at least partly receive integrated circuits and other components that protrude downwards into heat sink 34).

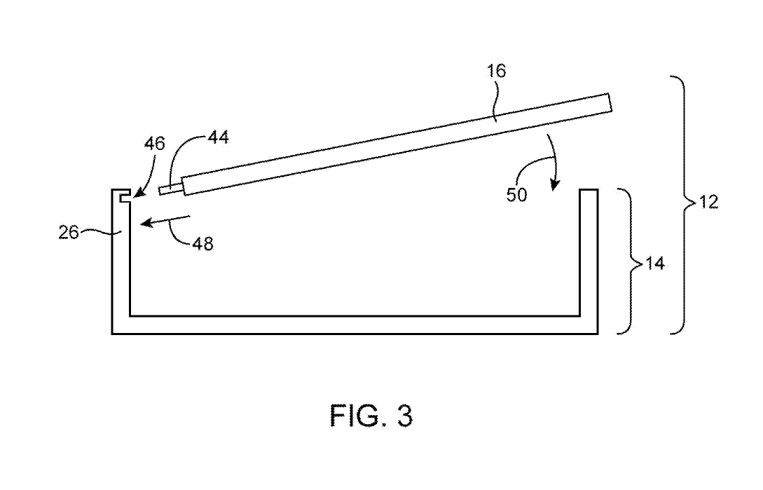

FIG. 3 is a side view of an illustrative configuration that may be used for housing 12. As shown in FIG. 3, protrusion 44 or other engagement features in lower housing 16 may be inserted in direction 48 into mating recess 46 or other engagement features in housing sidewalls 26 or other portions of upper housing 26. Following insertion of portion 44 of housing 16 into housing 14 in direction 48, housing 16 may be rotated in direction 50 so that hooks 30 (FIG. 2) engage snaps 18 (FIG. 1). If desired, protrusion 44 and recess 46 may be omitted and housing 16 may be inserted into housing 14 vertically (i.e., without rotation).

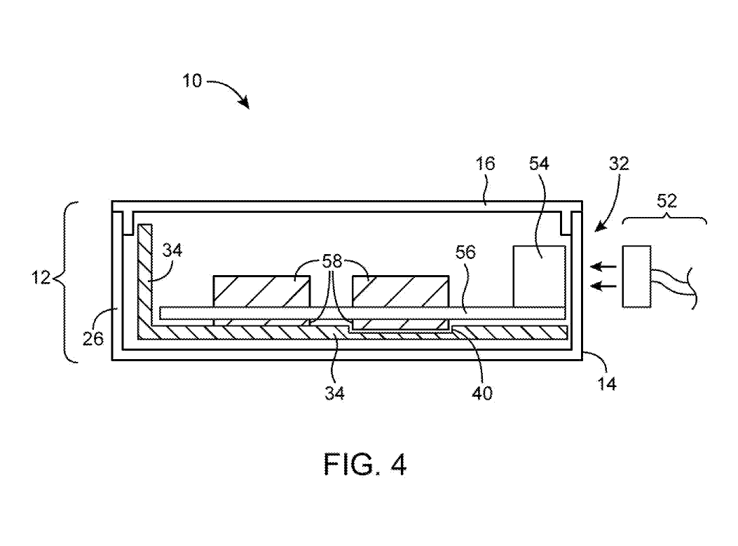

FIG. 4 is a cross-sectional side view of device 10 following assembly of housing portions 14 and 16. Openings such as openings 32 may be used to accommodate external connectors and cables. For example, connector 52 may be inserted through an opening in housing sidewall 26 such as opening 32 and may be received within mating connector 54. Connector 54 may be mounted on a printed circuit board or other suitable substrate. Substrate 56 may be formed from one or more rigid printed circuit boards (e.g., printed circuit boards formed from fiberglass-filled epoxy such as FR4 printed circuit boards), one or more flexible printed circuit boards (“flex circuits”) that include patterned metal traces on flexible polymer sheets such as polyimide sheets or other flexible dielectric layers, one or more molded plastic parts, or other suitable substrate structures. Components such as components 58 may be mounted on substrate 56, may be electrically coupled to substrate 56 (e.g., using flex circuit cables, wires, coaxial cables, and other suitable communications paths), and may otherwise be incorporated into the interior of device 10. Components 58 may include integrated circuits, discrete components such as resistors, capacitors, and inductors, switches, connectors (e.g., connectors such as connector 54), displays, microphones, speakers, light-emitting components, sensors, wireless circuitry, and other electrical devices. Heat sink 34 may be configured to gather and dissipate heat from components 58.

Engagement features such as snaps 18 of FIG. 1 may be implemented using a low-profile configuration (short vertical height) that consumes minimal volume within the interior of device 10, thereby enhancing the amount of space within device 10 that is available for mounting internal components 58.

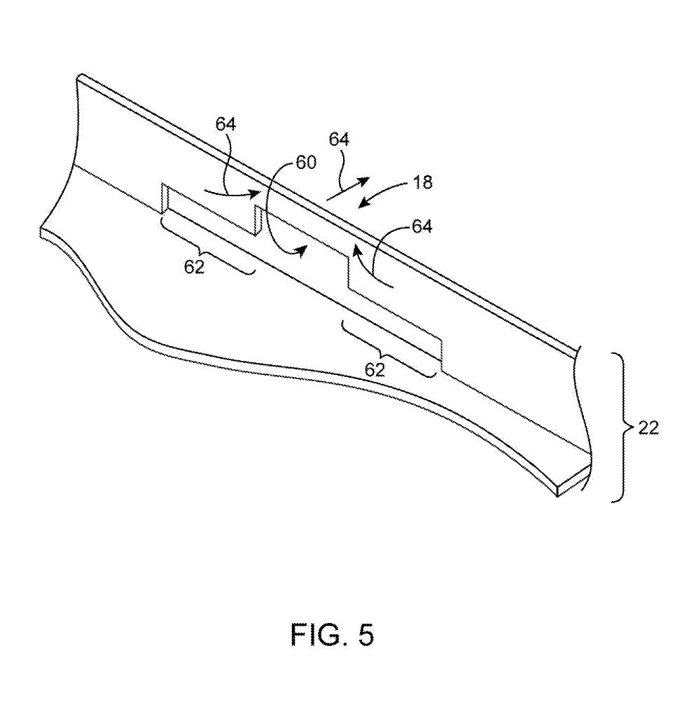

FIG. 5 is a perspective view of a portion of an illustrative low-profile snap structure. As shown in FIG. 5, snap structure 18 may include main opening portion 60 and contiguous side opening portions 62 that form lateral extensions to main portion 60 and create a T shape for the snap opening. Lateral extension portions 62 of the opening in FIG. 5 help to enlarge the width of the snap opening. Using a T shape of the type shown in FIG. 5 or other suitable shapes (e.g., rectangular openings, openings with curved edges, openings with combinations of curved and straight edges, circular openings, semi-circular openings, etc.), the structures of wall 22 of housing 16 that form snaps 18 may be provided with flexibility. This flexibility may allow the structures of each snap 18 to flex in directions such as directions 64 of FIG. 5 when forced into contact with hooks 30 (FIG. 2) during the process of mating housings 14 and 16.

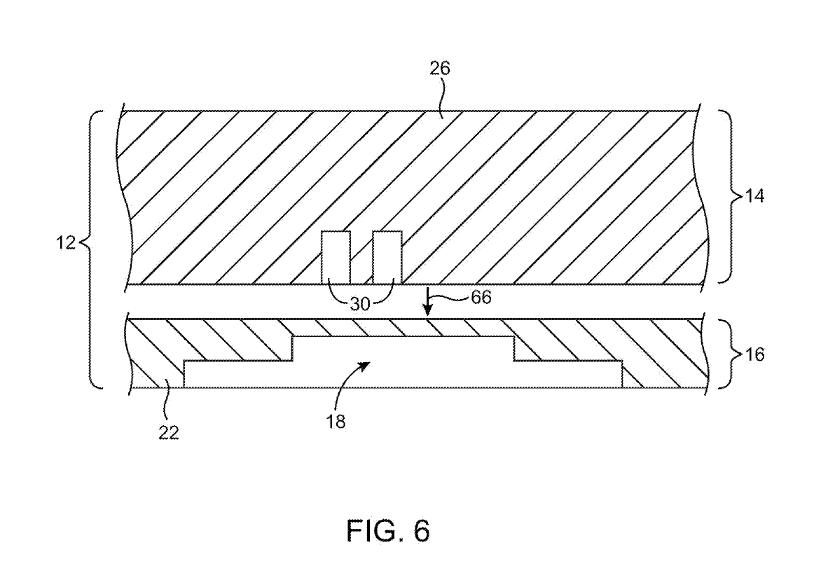

FIG. 6 shows how each snap 18 may be configured to mate with a pair of hooks 30 when upper housing 14 and lower housing 16 are moved together (e.g., by moving upper housing 14 in direction 66 towards lower housing 16).

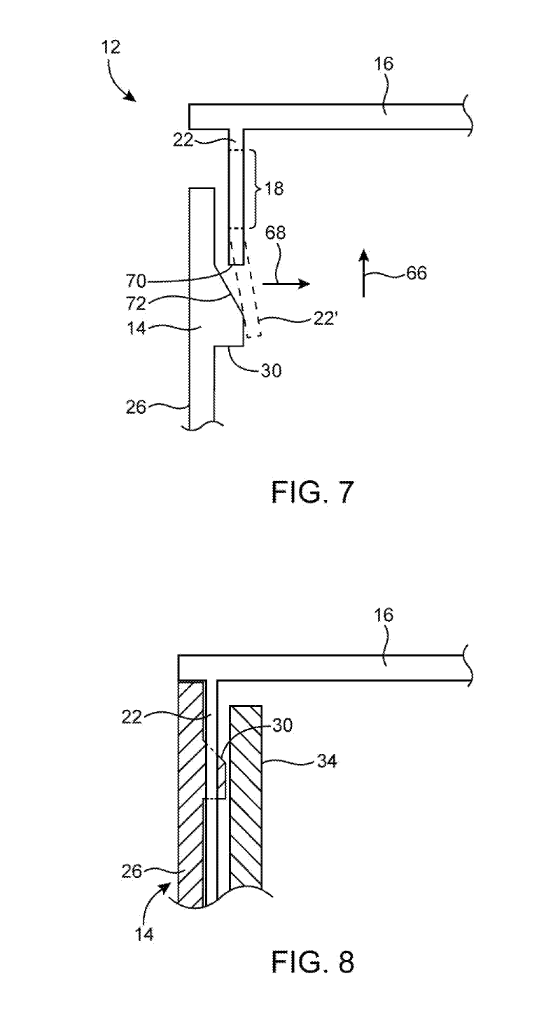

FIG. 7 is a cross-sectional side view of housing 12 as housing portions 14 and 16 are being assembled together by moving housing 14 in direction 66. Initially, wall 22 of housing 16 is not flexed (as shown in the solid lines of FIG. 7). As housings 16 and 14 are moved towards each other, tip 70 of sidewall 22 of housing 16 will bear against leading ramped surface 72 of hooks 30, causing wall portion 22 of housing 16 and snap 18 to flex into the flexed position illustrated by dashed line 22′.

Once housings 14 and 16 have been moved sufficiently close to each other, the opening associated with snap 18 will become aligned with hook 30, allowing wall portion 22 of housing 16 to return to its normal (unflexed) position with hook 30 received within snap 18 (see, e.g., FIG. 8). As shown in FIG. 8, vertically extending sidewall portions of heat sink 34 may be located adjacent to the interface between hooks 30 and snaps 18, thereby helping to prevent hooks 30 and snaps 18 from accidentally disengaging during a drop event in which device 10 is unintentionally struck by a rigid object or is otherwise subjected to a sharp impact.

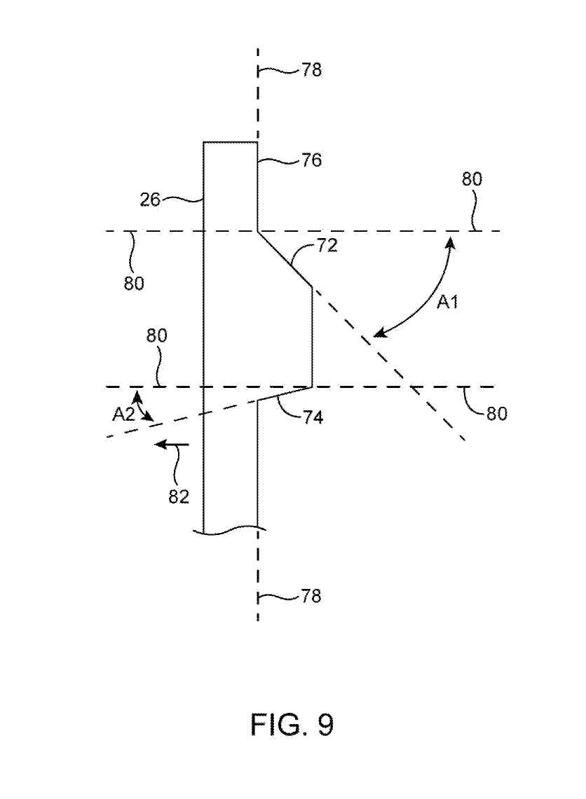

As shown in the cross-sectional side view of FIG. 9, inner housing wall surfaces 76 may be configured to run parallel to vertical axis 78. Leading ramp surface (leading edge) 72 may be oriented at a non-zero angle Al with respect to horizontal axis 80. Angle Al may be selected to be sufficiently large to encourage the flexing motion of snap feature 18 during assembly, as described in connection with FIG. 7. For example, surface 72 may be oriented at an angle of about 20-80°, about 30-70°, or other suitable angle (as examples). Trailing ramp surface (trailing edge) 74 of hook 30 may have an angle A2 of 0-75°, 0-45°, 3-20°, 4-15° or other suitable angle (e.g., a suitable non-zero angle). The use of non-zero values for angle A2 may create a built-in bias for wall 26 in direction 82, away from snap 18 and wall 22. By using trailing ramp surface 74 to bias hook 30 and wall 26 away from snap 18 and wall 22, undesirable rattling in device 10 due to movement between housing portions 14 and 16 may be minimized.

The foregoing is merely illustrative of the principles of this invention and various modifications can be made by those skilled in the art without departing from the scope and spirit of the invention.

What is claimed is:

1. An electronic device, comprising:
mating first and second housing structures;
inwardly protruding hook structures at each of four corners of the first housing structure; and
snap structures at each of four corners of the second housing structure, wherein the snap structures each include an opening that receives a respective one of the hook structures.

2. The electronic device defined in claim 1 wherein the snap structures each include a main opening and two lateral extension openings that form a T-shaped opening.

3. The electronic device defined in claim 2 wherein the first housing structure comprises an upper housing and wherein the second housing structure comprises a lower housing.

4. The electronic device defined in claim 3 further comprising:
a substrate mounted within the first and second housing structures; and
electronic components mounted on the substrate.

5. The electronic device defined in claim 4 further comprising a heat sink structure that is configured to receive heat from the electronic components.

6. The electronic device defined in claim 5 wherein the heat sink comprises a vertical portion adjacent to at least one of the hooks and one of the snap structures.

7. The electronic device defined in claim 6 wherein the heat sink includes at least one recessed portion that receives at least part of one of the electronic components.

8. The electronic device defined in claim 1 wherein each of the hook structures has a leading edge configured to bear against a corresponding one of the slot structures as the first and second housing structures move towards each other.

9. The electronic device defined in claim 8 wherein each of the hook structures has a trailing edge that biases the hook structure away from the snap structure.

10. The electronic device defined in claim 1 wherein the four corners of the first housing comprise four curved corners.

11. The electronic device defined in claim 10 wherein the first housing comprises an upper housing having a planar top surface and four vertical sidewalls and wherein the second housing comprises a planar housing member.

12. The electronic device defined in claim 1 wherein the first and second housing structures each have four edges, the electronic device further comprising:
additional inwardly protruding hook structures located midway along at least some of the four edges of the first housing structure; and
additional snap structures located midway along at least some of the four edges of the second housing structure, wherein the additional snap structure each include an opening that receives a respective one of the additional hook structures.

13. The electronic device defined in claim 1 wherein each of the hook structures comprises two hooks.

14. The electronic device defined in claim 1 wherein the second housing comprises a lower housing having a lip that is configured to be received within an opening in the first housing, and wherein each of the snap structures is formed in the lip and comprises a portion that flexes inwardly when contacted by a corresponding one of the hook structures as the first and second housing structures are assembled together.

15. Electronic device housing structures, comprising:
a first housing having a first planar member and four sidewalls perpendicular to the first planar member, wherein the four sidewalls have edges that define a substantially rectangular opening;
a second housing having a second planar member with a substantially rectangular periphery and having a lip that runs around the periphery, wherein the lip is configured to be received within the rectangular opening;
first engagement structures on the first housing along the first edges; and
second engagement structures that are configured to mate with the first engagement structures and that are formed from openings in the lip of the second housing.

16. The electronic device housing structures defined in claim 15 wherein the first engagement structures comprises inwardly protruding hook structures.

17. The electronic device housing structures defined in claim 16 wherein the second engagement structures each comprise T-shaped openings in the lip.

18. The electronic device housing structures defined in claim 16 wherein the lip has four lip edges and four lip corners and wherein the snap structures are formed on at least some of the four lip edges and are formed at each of the four corners.

19. Housing structures, comprising:
an upper housing having four corners, wherein the upper housing has sidewalls with edges that define an opening;
a lower housing having a planar structure that mates with the opening;
inwardly protruding structures at the corners of the upper housing; and
four corner openings at corner portions of the planar structure that receive the inwardly protruding structures.

20. The housing structures defined in claim 19 wherein the inwardly protruding structures comprise hook structures each of which has an angled leading edge and an angled trailing edge, wherein the angled leading edges are configured to flex portions of the second housing in response to movement of the upper housing towards the lower housing.
